(19) United States
(12) Patent Application Publication
(10) Pub. No.: US 2004/0264275 A1
(43) Pub. Date: Dec. 30, 2004

(54) Precharge apparatus in semiconductor memory device and precharge method using the same

(75) Inventor: Ja Seung Gou, Kyungki-Do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyungki-Do (KR)

(21) Appl. No.: 10/742,313

(22) Filed: Dec. 19, 2003

(30) Foreign Application Priority Data
Jun. 27, 2003 (KR) 2003-42422

(51) Int. Cl. G11C 7/00

(52) U.S. Cl. 365/203

(57) ABSTRACT

Disclosed is a precharge apparatus in a semiconductor memory device and a precharge method using the same. The precharge apparatus includes a memory array in which a plurality of memory banks are divided into at least two memory groups, and a precharge all command decoder to generate at least two precharge signals according to a precharge command signal and an address signal, wherein the at least two precharge signals are each output with a time lag according to a control signal to precharge the ate least two memory groups with a time lag. Therefore, the peak current is distributed to reduce the power bouncing.

### BACKGROUND

1. Technical Field of the Invention

The present patent relates to a precharge apparatus in a semiconductor memory device and a precharge method using the same, and more particularly, to a precharge method in a DDRII SDRAM and a precharge method using the same.

2. Discussion of Related Art

In order to improve the operating speed of the DRAM, the synchronous DRAM (hereinafter referred to simply as ‘SDRAM’) that is synchronized to an external system clock was developed.

Further, in order to further improve the data processing speed, a double data rate (hereinafter referred to as ‘DDR’) SDRAM that is synchronized to the rising edge and the falling edge of one clock to process data and Rambus DRAM were developed.

In the DDRII SDRM, the memory array consists of a plurality of banks. At the time of a precharge all command operation, pairs of bit lines in all the banks are precharged with a certain level.

A conventional precharge operation will now be described with reference to FIG. 1 and FIG. 2.

As shown in FIG. 1, a memory array 100 includes a plurality of banks 31 to 38. A precharge command decoder 10 generates a precharge command signal Pre_Com according to control signals WEb, CSb and RASb. A precharge all command decoder 20 generates one precharge signal out according to an address signal A10 and the precharge command signal Pre_Com. All the banks 31 to 38 are precharged by the precharge signal out.

The operation of the precharge all command decoder 20 will now be described in detail with reference to FIG. 2.

If the address signal A10 and the precharge command signal Pre_Com are in a HIGH state, the output of a NAND gate G1 becomes a LOW state. As the output of the NAND gate G1 is inverted in an inverter G3, the output of the inverter G3 becomes a HIGH state. As the output of the inverter G3 is inverted in an inverter G2 and is then supplied to the input terminal of the inverter G3, the output of the inverter G3 holds the HIGH state. At this time, coupling of the inverters G2 and G3 is called a latch 40. In other words, the output of the NAND gate G1 is held with it inverted in the latch 40.

As such a precharge operation is performed in all the banks at a time, a level bouncing of the power occurs. The level bouncing causes an effective supply level to be further reduced in the DDRII SDRAM that uses the power lower than the DDR SDRAM.

### SUMMARY OF THE INVENTION

The disclosed embodiments are directed to provide a precharge apparatus in a semiconductor memory device and a precharge method using the same.

As shown in the disclosed embodiments, in the DDRII SDRAM, the memory is divided into at least two groups wherein the precharge all command operation is performed. Thereby, as the peak current is distributed, the power bouncing is reduced.

According to one aspect of the disclosed embodiments, there is provided a precharge apparatus in a semiconductor memory device, including a memory array in which a plurality of memory banks are divided into at least two memory groups, and a precharge all command decoder to generate at least two precharge signals according to a precharge command signal and an address signal, wherein the at least two precharge signals are each output with a time lag according to a control signal to precharge the at least two memory groups with a time lag.

According to another aspect of the disclosed embodiments, there is provided a precharge method in a semiconductor memory device, including the steps of providing a memory array in which eight memory banks are divided into two memory groups each having four memory banks, generating a precharge command signal, and generating first and second precharge signals according to the precharge command signal and an address signal at the time of a precharge all command operation, wherein the first and second precharge signals are each output with a time lag according to a control signal to precharge the two memory groups with a time lag.

### BRIEF DESCRIPTION OF THE DRAWINGS

The above and other objects, features and advantages of the disclosed embodiments will become apparent from the following description of disclosed embodiments given in conjunction with the accompanying drawings, in which:

FIG. 1 is a block diagram illustrating a conventional precharge apparatus;

FIG. 2 is a detailed circuit diagram illustrating a precharge all command decoder shown in FIG. 1;

FIG. 3 is a block diagram illustrating an embodiment of a precharge apparatus;

FIG. 4 is a detailed circuit diagram illustrating a precharge all command decoder shown in FIG. 3; and

FIG. 5 is a waveform for illustrating the operation of the precharge all command decoder shown in FIG. 4.

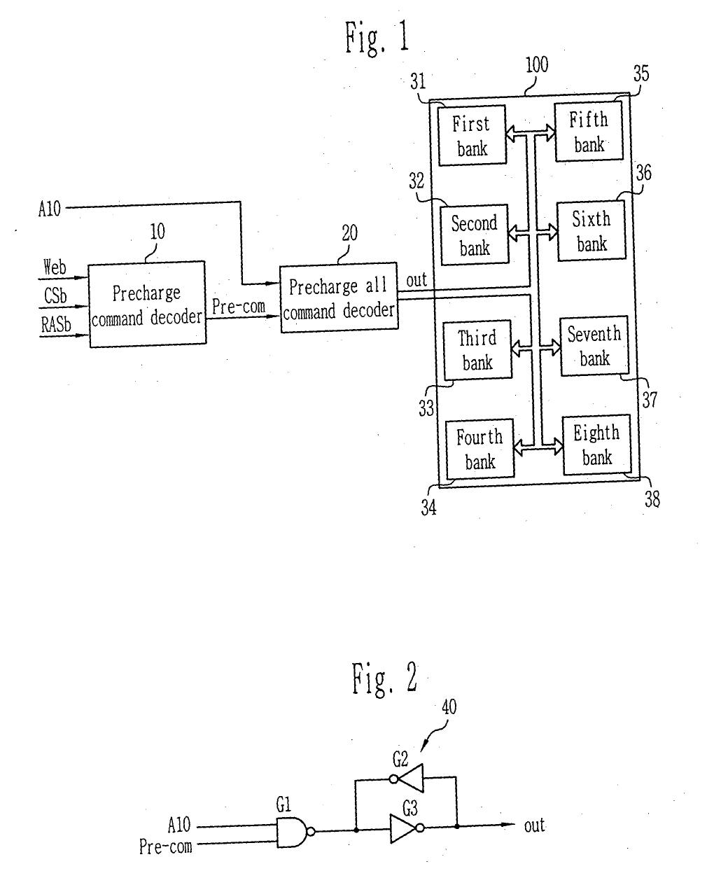

### DETAILED DESCRIPTION OF PREFERRED EMBODIMENTS

Hereinafter, a precharge apparatus and a precharge method using the same according to the disclosed embodiments will be described in detail with reference to the accompanying drawings.

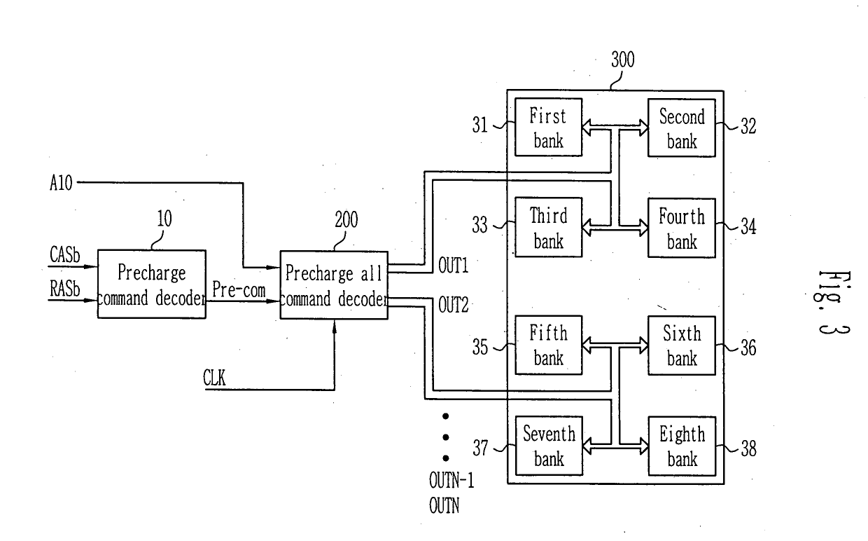

FIG. 3 is an exemplary block diagram illustrating a precharge apparatus. As shown in FIG. 3, a memory array 300 includes of a plurality of banks 31 to 38. The first to fourth banks 31 to 34 constitute one memory group and the fifth to eighth banks 35 to 38 constitute the other memory group. That is, the memory array 300 is composed of two groups.

A precharge command decoder 10 generates a precharge command signal Pre_Com according to control signals WEb, CSb and RASb. A precharge all command decoder 200 generates first and second precharge signals OUT1 and OUT2 according to an address signal A10 (for example, an automatic precharge signal), the precharge command signal Pre_Com and a control signal CLK. At this time, a clock signal in the form of a pulse may be used as the control signal CLK. The second precharge signal OUT2 is delayed as much as the time where the clock signal is toggled than the first precharge signal OUT1. The first to fourth banks 31 to 34 are precharged by the first precharge signal OUT1 and the fifth to eighth banks 35 to 38 are then precharged by the second precharge signal OUT2.

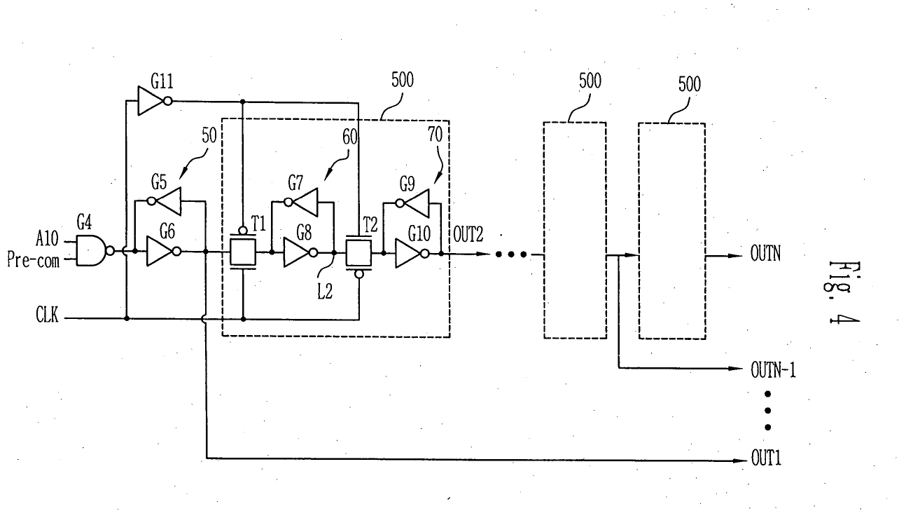

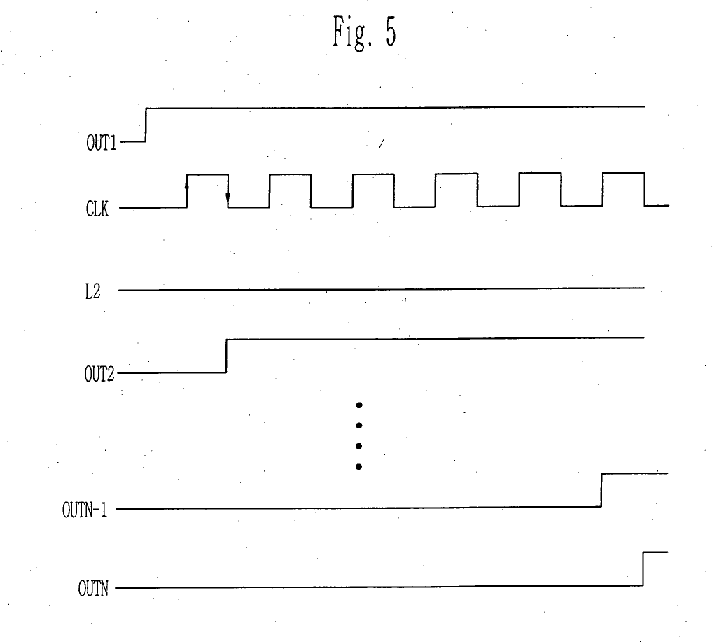

The operation of the precharge all command decoder 200 will now be described in detail with reference to FIG. 4 and FIG. 5.

If the address signal A10 and the precharge command signal Pre_Com are in a HIGH state, the output of an inverter gate G4 becomes a LOW state. As the output of the inverter gate G4 is inverted in an inverter G6, the output of the inverter G6 becomes a HIGH state. As the output of the inverter G6 is inverted in an inverter G5 and is then applied to the input terminal of the inverter G6, the output of the inverter G6 holds the HIGH state. Coupling of the inverters G5 and G6 may be referred to as a latch 50. In other words, the output of the inverter gate G4 is held with it inverted in the latch 50. The output of the latch 50 becomes the first precharge signal OUT1 and the first to fourth banks 31 to 34 in FIG. 4 are precharged at the same time by the first precharge signal OUT1.

After a lapse of a certain time period, if the control signal CLK becomes a HIGH state, the output of an inverter G11 becomes a LOW state. A transmission gate T1 is thus turned on. Therefore, as the output of the latch 50 is inverted in an inverter G8, the output of the inverter G8 becomes a LOW state. As the output of the inverter G8 is inverted in an inverter G7 and is then applied to the input terminal of the inverter G8, the output of the inverter G8 holds the LOW state, as shown in the waveform L2 of FIG. 5. Coupling of the inverters G7 and G8 may be referred to as a latch 60. That is, the output of the latch 50 is held with it inverted in the latch 60.

Thereafter, if the control signal CLK becomes a LOW state, as the output of the inverter G11 becomes a HIGH state, a transmission gate T2 is turned on. Therefore, as the output of the latch 60 is inverted in an inverter G10, the output of the inverter G10 becomes a HIGH state. As the output of the inverter G10 is inverted in an inverter G9 and is then applied to the input terminal of the inverter G10, the output of the inverter G10 holds the HIGH state. Coupling the inverters G9 and G10 may be referred to as a latch 70. In other words, the output of the latch 60 is held with it inverted in the latch 70. The output of the latch 70 becomes the second precharge signal OUT2 and the fifth to eighth banks 35 to 38 in FIG. 4 are precharged at the same time by the second precharge signal OUT2.

In other words, after the first to fourth banks 31 to 34 are precharged, for example, after a time delay of one clock cycle, the fifth to eighth banks 35 to 38 are precharged. Therefore, the peak current is distributed to reduce the power bouncing.

It has been described in the above embodiment that the memory array 300 has a plurality of banks that are divided into the two groups. However, it will be evident to those skilled in the art that the memory array can be divided into a plurality of groups of two or more. In the case where the memory array 300 is divided into the plurality of the groups of two or more, a dotted block 500 in FIG. 4 is repeatedly constructed to generate the precharge signals OUT1, OUT2, . . . OUTN-1, OUTN of the same number as the memory group. Of course, the precharge signal has only a time lag as described above.

According to the embodiments described above, in the DDRII SDRAM, the memory is divided into at least two groups wherein the precharge all command operation is performed. Thereby, the peak current is distributed to reduce the power bouncing.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

What is claimed is:

1. A precharge apparatus in a semiconductor memory device, the precharge apparatus being connected to a memory array having a plurality of memory banks divided into at least two memory groups and comprising:
a precharge all command decoder to generate at least two precharge signals according to a precharge command signal and an address signal, wherein the at least two precharge signals are output respectively with a time lag according to a control signal to precharge the at least two memory groups with a time lag.

2. The precharge apparatus as claimed in claim 1, wherein the precharge all command decoder comprises:
a NAND gate to perform a NAND operation on the precharge command signal and the address signal;
a first latch to latch the output of the NAND gate to generate a first precharge signal;
a first transmission gate that is turned on when the control signal becomes a HIGH state;
a second latch to latch the output of the first latch via the first transmission gate;
a second transmission gate that is turned on when the control signal becomes a LOW state; and
a third latch to latch the output of the second transmission gate via the second transmission gate to generate a second precharge signal.

3. The precharge apparatus as claimed in claim 2, wherein the first latch comprises:
a first inverter to invert the output of the NAND gate; and
a second inverter to invert the output of the first inverter and then to apply the inverted output to the input terminal of the first inverter.

4. The precharge apparatus as claimed in claim 2, wherein the second latch comprises:
a first inverter to invert the output of the first latch via the first transmission gate; and
a second inverter to invert the output of the first inverter and then to apply the inverted output to the input terminal of the first inverter.

5. The precharge apparatus as claimed in claim 2, wherein the third latch comprises:
a first inverter to invert the output of the second latch via the second transmission gate; and
a second inverter to invert the output of the first inverter and then to apply the inverted output to the input terminal of the first inverter.

6. A precharge apparatus in a semiconductor memory device, the precharge apparatus connected to a memory array having eight memory banks divided into two memory groups and comprising:
a precharge command decoder to generate a precharge command signal; and
a precharge all command decoder to generate a first and a second precharge signal according to the precharge command signal and an address signal at the time of a precharge all command operation, wherein the first and second precharge signals are output respectively with a time lag according to a control signal to precharge the two memory groups with a time lag.

7. The precharge apparatus as claimed in claim 6, wherein the precharge all command decoder comprises:
a NAND gate to perform a NAND operation on the precharge command signal and the address signal;
a first latch to latch the output of the NAND gate to generate the first precharge signal;
a first transmission gate that is turned on when the control signal becomes a HIGH state;
a second latch to latch the output of the first latch via the first transmission gate;
a second transmission gate that is turned on when the control signal becomes a LOW state; and
a third latch to latch the output of the second transmission gate via the second transmission gate to generate a second precharge signal.

8. The precharge apparatus as claimed in claim 6, wherein the first latch comprises:
a first inverter to invert the output of the NAND gate; and
a second inverter to invert the output of the first inverter and then to apply the inverted output to the input terminal of the first inverter.

9. The precharge apparatus as claimed in claim 6, wherein the second latch comprises:
a first inverter to invert the output of the first latch via the first transmission gate; and
a second inverter to invert the output of the first inverter and then to apply the inverted output to the input terminal of the first inverter.

10. The precharge apparatus as claimed in claim 6, wherein the third latch comprises:
a first inverter to invert the output of the second latch via the second transmission gate; and
a second inverter to invert the output of the first inverter and then to apply the inverted output to the input terminal of the first inverter.

11. The precharge apparatus as claimed in claim 6, wherein the precharge all command decoder comprises:
a NAND gate to perform a NAND operation on the precharge command signal and the address signal;
a first inverter to invert the output of the NAND gate to generate the first precharge signal;
a second inverter to invert the output of the first inverter and then to supply the inverted output to the input terminal of the first inverter;
a third inverter to invert the output of the control signal;
a first transmission gate that is turned on according to the output of the third inverter and the control signal;
a fourth inverter to invert the signal via the first transmission gate;
a fifth inverter to invert the output of the fourth inverter and then to supply the inverted output to the input terminal of the fourth inverter;
a second transmission gate that is turned on according to the output of the third inverter and the control signal;
a sixth inverter to invert the signal via the second transmission gate to generate the second precharge signal; and
a seventh inverter to invert the output of the sixth inverter and then to supply the inverted output to the input terminal of the sixth inverter.

12. A precharge method for precharging cells of a memory array in which a plurality of memory banks are divided into at least two memory groups, in a semiconductor memory device, wherein the precharge method comprises:
generating at least two precharge signals according to a precharge command signal and an address signal, wherein the at least two precharge signals are output respectively with a time lag according to a control signal to precharge the at least two memory groups with a time lag.

13. A precharge method in a semiconductor memory device, comprising:
providing a memory array in which eight memory banks a re divided into two memory groups each having four memory banks;
generating a precharge command signal; and
generating a first and a second precharge signal according to the precharge command signal and an address signal at the time of a precharge all command operation, wherein the first and the second precharge signals are output respectively with a time lag according to a control signal to precharge the two memory groups with a time lag.

14. The method as claimed in claim 13, wherein the control signal is a clock signal in a type of a pulse and wherein the second precharge signal is generated with the clock signal delayed as much as the time where the clock signal is delayed.
